(19) United States
(12) Patent Application Publication
(10) Pub. No.: US 2011/0248378 A1
(43) Pub. Date: Oct. 13, 2011

(54) SEMICONDUCTOR DEVICE

(75) Inventors: Hwa Chul LEE, Icheon (KR); Jeong Won Kang, Icheon (KR)

(73) Assignee: Hynix Semiconductor Inc., Icheon (KR)

(21) Appl. No.: 12/972,337

(22) Filed: Dec. 17, 2010

(30) Foreign Application Priority Data
Apr. 12, 2010 (KR) 10-2010-0033457

(51) Int. Cl. H01L 23/525

(52) U.S. Cl. 257/529; 257/E23.149

(57) ABSTRACT

A semiconductor device is disclosed. The semiconductor device includes a first line, a second line spaced apart from the first line, a contact formed over the first line and the second line, a fuse coupled to the contact, and a dummy pattern configured to couple the fuse to the contact.

### CROSS-REFERENCE TO RELATED APPLICATION

The present application claims priority to Korean patent application number 10-2010-0033457, filed on 12 Apr. 2010, which is incorporated by reference in its entirety.

### BACKGROUND OF THE INVENTION

Embodiments of the present invention relate to a semiconductor device, and more particularly to a technology of a fuse that is contained in a highly-integrated semiconductor device so as to transmit an electric signal and decide whether two different terminals are interconnected.

Generally, a fuse is defined as an automatic circuit breaker for preventing overcurrent from continuously flowing through an electric power line. That is, the fuse is melted by heat generated by an electric current so that the electric line is severed. Fuses have been widely used throughout the world to protect an objective circuit from overcurrent. The fuse allows the current to continuously flow in the circuit. However, assuming that the fuse is severed and is not replaced with a new fuse, the severed fuse permanently prevents the current from flowing so that it is different from a switch capable of blocking or connecting the current flow.

Semiconductor devices are designed to be used for predetermined purposes by implanting impurities or depositing a new material at a predetermined region contained in a silicon wafer. A representative example of the semiconductor devices may be a semiconductor memory device. The semiconductor memory device includes a large number of elements to carry out given purposes, for example, transistors, capacitors, resistors, and the like. The semiconductor memory device may further include fuses. The fuses are used at several places of the semiconductor memory device. Representative examples of the fuses include a redundancy circuit, a power supply circuit, and the like. Although the fuses used in such circuits maintain a normal status in a fabrication process, the fuses may also be selectively blown (severed) through several tests upon completion of the fabrication process.

### BRIEF SUMMARY OF THE INVENTION

Various embodiments of the present invention are directed to providing a semiconductor device that substantially obviates one or more problems due to limitations and disadvantages of the related art.

An object of the present invention is to provide a fuse for use in a semiconductor device, wherein both ends of the fuse are not directly coupled to lines (or wirings) contained in the semiconductor device, and are electrically coupled through an additional dummy pattern composed of a contact and a conductive layer, so that an larger process range is available.

In accordance with an aspect of the present invention, a semiconductor device comprising: a first line; a second line spaced apart from the first line; first and second contact patterns formed over the first line and the second line, respectively; a fuse configured to couple the first contact pattern and the second contact pattern; and a first dummy pattern configured to couple the fuse to the first contact pattern.

The fuse includes copper (Cu). The device further comprising: a barrier metal film formed at a lower part and sidewalls of the fuse, and an insulating film formed over the fuse.

The insulating film includes a nitride film. The barrier metal film includes titanium nitride (TiN). The first dummy pattern includes: a first dummy plug coupled to the first contact pattern; a first dummy contact pattern coupled to the first dummy plug; and a first dummy line coupled to the first dummy contact pattern; a second dummy contact pattern coupled to the first dummy line and the fuse.

The device further comprising a second dummy pattern configured to couple the fuse to the second contact pattern, wherein a fuse open region is formed between the first and the second dummy patterns. The first line and the second line are spaced apart from each other by a predetermined length longer than a length corresponding to the sum of the fuse and the first dummy line.

The first dummy line is formed at a greater distance further from the base of the semiconductor substrate than the fuse. electrical connection between the first line and the second line is severed when the fuse is blown by a laser.

In accordance with an aspect of the present invention, semiconductor device comprising: a first device element; a second device element; a fuse coupled to the second device element; and a first dummy pattern coupled the fuse to the first device element. The fuse is separated from the first device element and coupled to the first device element through the first dummy pattern.

The fuse is located between the first and the second device elements. The first device element comprises: a first underlying element; and a first contact pattern coupled to the first dummy pattern.

The first dummy pattern comprises: a first dummy plug coupled to the first device element; a first dummy line formed over the first dummy plug; a first dummy contact pattern coupled to the first dummy plug and the first dummy line; and a second dummy contact pattern coupling the first dummy line to the fuse.

The first dummy pattern is formed at a distance further from the base of the substrate than the fuse. Further comprising a second dummy pattern configured to couple the fuse to the second device element, wherein the fuse is physically separated from the second device element and electrically coupled to the second device element through the second dummy pattern.

The dummy line may be formed at a higher position from a semiconductor substrate so that the formed position of the dummy line is higher than that of the fuse. Electrical connection between the first line and the second line may be severed when the fuse is blown by laser scanning.

### BRIEF DESCRIPTION OF THE DRAWINGS

FIG. 1 is a conceptual diagram illustrating a fuse blowing process.

FIGS. 2A and 2B are cross-sectional views illustrating the problems of a conventional semiconductor device.

FIGS. 3A and 3B are cross-sectional views illustrating a semiconductor device according to one embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

According to the semiconductor device of the present invention, both ends of a fuse are not directly coupled to lines of the semiconductor device, and are electrically coupled through an additional dummy pattern composed of a contact and a conductive layer, so that a larger process range is available. Thus, although the dummy patterns formed at both ends of the fuse are damaged, other elements for the semiconductor device are not affected. This dummy pattern increases the fuse length or width, and thus likelihood of causing damage to functional elements is decreased.

In recent times, with the increasing degree of integration of semiconductor devices, the scale of design rules has been reduced. As the scale of design rules is reduced, the fuse contained in the semiconductor device is also reduced in size, so that a more precise fuse blowing process is needed.

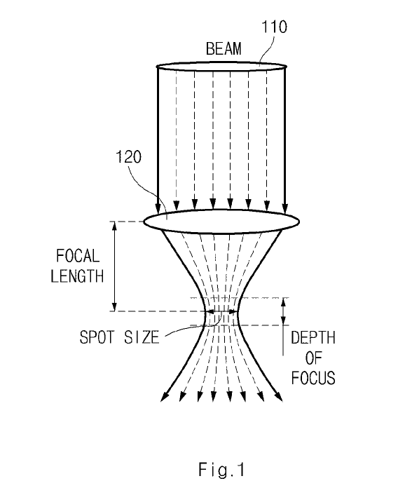

FIG. 1 is a conceptual diagram illustrating a fuse blowing process.

Referring to FIG. 1, the fuse blowing process uses a laser beam radiated from a light source 110 through a lens 120. The laser beam passing through the lens 120 travels by a predetermined distance corresponding to a focal length before arriving at the fuse. The size of the affected area where the blowing occurs is as broad as the spot size at the depth of focus.

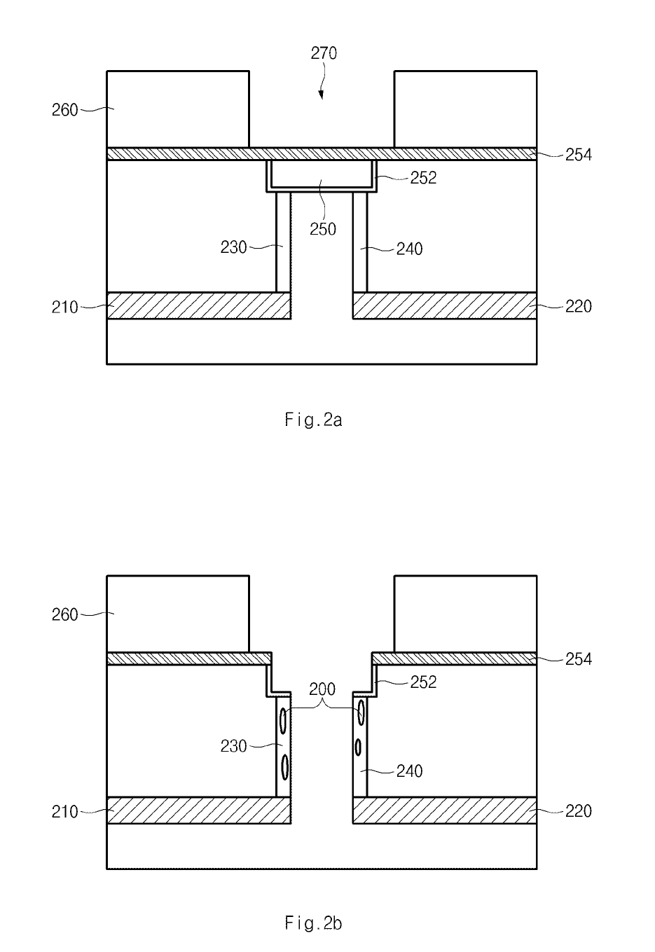

FIGS. 2A and 2B are cross-sectional views illustrating the problems of a general semiconductor device.

Referring to FIG. 2A, a contact 230 is formed over one line 210 formed on a semiconductor substrate, and a contact 240 is formed over the other line 220 formed on the semiconductor substrate. The contacts 230 and 240 are interconnected through a fuse 250. The fuse 250 includes copper (Cu). A barrier metal film 252 is formed at the bottom and sidewalls of the fuse 250. An insulating film 254 is formed over the fuse 250. A fuse open region 270 is defined on the insulating film 254 by a passivation layer 260.

FIG. 2B shows the result of the blowing process performed on the fuse 250. As the length and width of the fuse 250 are reduced in proportion to the scaled-down design rule, the fuse 250 is smaller than the fuse open region 270. As can be seen from FIG. 2B, due to the blowing process, not only the fuse 250 but also some parts of the contacts 230 and 240 formed below the fuse 250 are damaged, and empty spaces 200 are formed. To maintain the diminishing scale of semiconductors, it is desirable to reduce the spot size and the depth of focus. However, when the spot size and the depth of focus are reduced, it is difficult to control the blowing process. As a result, not only the fuse 250, but also the contacts 230 and 240 formed below the fuse 250 can be easily damaged. When other device elements are damaged during the fuse blowing, resistance is increased so that the operation stability of the semiconductor device is deteriorated.

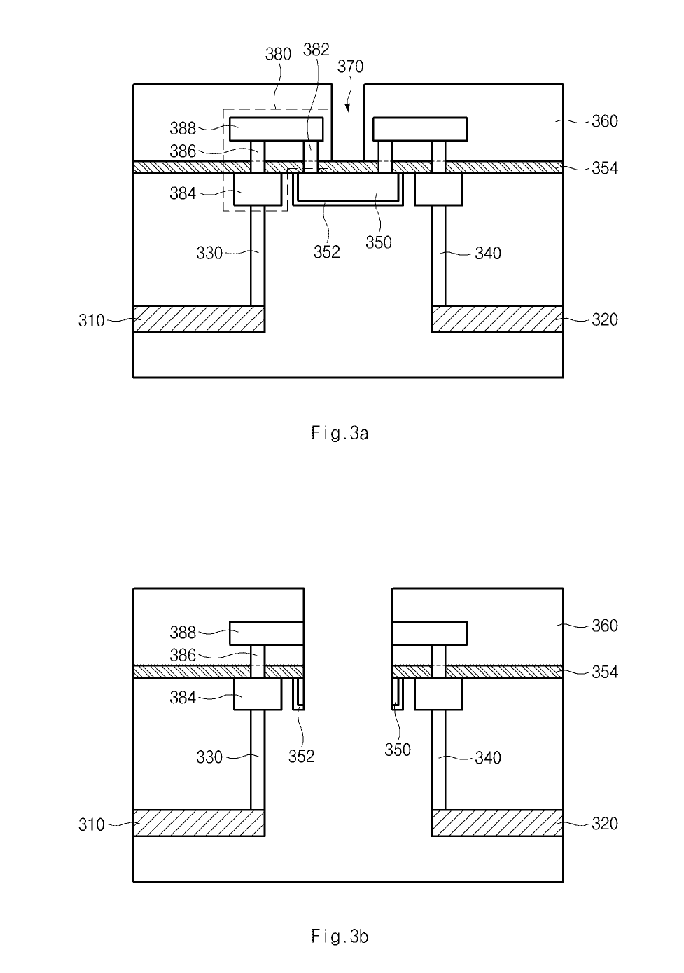

FIGS. 3A and 3B are cross-sectional views illustrating a semiconductor device according to one embodiment of the present invention.

Referring to FIG. 3A, a first line 310 and a second line 320 that are formed over the semiconductor substrate are electrically interconnected through a fuse 350. The fuse 350 may include copper (Cu). A barrier metal film 352 is formed at the bottom and sidewalls of the fuse 350, and an insulating film 354 is formed over the fuse 350. The insulating film 354 may include a nitride film, and the barrier metal film 352 includes titanium nitride (TiN).

A fuse open region 370 is defined on the insulating film 354 by a passivation layer 360. Unlike the conventional art, the semiconductor device according to the present invention further includes a dummy pattern 380 located between the fuse 350 and the contact 330 formed over the first line 310, and a second dummy pattern located between the fuse 350 and the contact 340 formed over second line 320. That is, the dummy pattern 380 is formed at both ends of the fuse 350. The fuse open region 370 is located over the fuse 350 and between neighbor dummy patterns 380.

The dummy pattern 380 includes a first dummy contact 382 formed on the fuse 350, a dummy plug 384 coupled to the contacts 330 and 340, a second dummy contact 386 formed over the dummy plug 384, and a dummy line 388 electrically coupling the first dummy contact 382 to the second dummy contact 386.

FIG. 3B shows the result of a blowing process performed on the fuse 350. When the fuse 350 exposed by the fuse open region 370 is blown, the peripheral regions of the fuse 350 are also damaged. However, compared to the conventional art, the semiconductor device according to the present invention allows the dummy pattern 380 formed at both ends of the fuse 350 to protect device elements around the blown fuse 350. That is, since the fuse 350 is indirectly coupled through the dummy patterns 380 to substantial device elements such as the first and the second contacts 330 and 340 and the first and the second lines 310 and 320, the dummy pattern 380 is damaged or lost rather than the substantial device elements during the blowing process of the fuse 350.

It is apparent from the above description that although the length and width of the fuse are reduced in proportion to the reducing scale in the related art, embodiments of the present invention can allow for a larger process range by using a dummy pattern. When the scale of device elements is reduced so that semiconductor device elements located below the fuse can be easily damaged, the distance between the device elements e and the fuse can be kept relatively large because of the dummy pattern. As a result, the semiconductor device according to the present invention can prevent the functional device elements from being damaged in the blowing process. The dummy pattern increases the effective range of the blowing process parameters, and also increases the operational stability of the semiconductor device.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a first line;
a second line spaced apart from the first line;
first and second contact patterns formed over the first line and the second line, respectively;
a fuse configured to couple the first contact pattern and the second contact pattern; and
a first dummy pattern configured to couple the fuse to the first contact pattern.

2. The semiconductor device according to claim 1, wherein the fuse includes copper (Cu).

3. The semiconductor device according to claim 1, the device further comprising:
a barrier metal film formed at a lower part and sidewalls of the fuse, and
an insulating film formed over the fuse.

4. The semiconductor device according to claim 3, wherein the insulating film includes a nitride film.

5. The semiconductor device according to claim 3, wherein the barrier metal film includes titanium nitride (TiN).

6. The semiconductor device according to claim 1, wherein the first dummy pattern includes:
a first dummy plug coupled to the first contact pattern;
a first dummy contact pattern coupled to the first dummy plug; and
a first dummy line coupled to the first dummy contact pattern.
a second dummy contact pattern coupled to the first dummy line and the fuse.

7. The semiconductor device according to claim 6, the device further comprising a second dummy pattern configured to couple the fuse to the second contact pattern,
wherein a fuse open region is formed between the first and the second dummy patterns.

8. The semiconductor device according to claim 6, wherein the first line and the second line are spaced apart from each other by a predetermined length longer than a length corresponding to the sum of the fuse and the first dummy line.

9. The semiconductor device according to claim 6, wherein the first dummy line is formed at a greater distance further from the base of the semiconductor substrate than the fuse.

10. The semiconductor device according to claim 1, wherein electrical connection between the first line and the second line is severed when the fuse is blown by a laser.

11. A semiconductor device comprising:
a first device element;
a second device element;
a fuse coupled to the second device element; and
a first dummy pattern coupled the fuse to the first device element.

12. The semiconductor device of claim 11, wherein the fuse is separated from the first device element and coupled to the first device element through the first dummy pattern.

13. The semiconductor device of claim 11, wherein the fuse is located between the first and the second device elements.

14. The semiconductor device of claim 11, wherein the first device element comprises:
a first underlying element; and
a first contact pattern coupled to the first dummy pattern.

15. The semiconductor device of claim 11, wherein the first dummy pattern comprises:
a first dummy plug coupled to the first device element;
a first dummy line formed over the first dummy plug;
a first dummy contact pattern coupled to the first dummy plug and the first dummy line; and
a second dummy contact pattern coupling the first dummy line to the fuse.

16. The semiconductor device of claim 11, wherein the first dummy pattern is formed at a distance further from the base of the substrate than the fuse.

17. The semiconductor device of claim 11, further comprising a second dummy pattern configured to couple the fuse to the second device element,
wherein the fuse is physically separated from the second device element and electrically coupled to the second device element through the second dummy pattern.
